(19) United States
(12) Patent Application Publication
(10) Pub. No.: US 2007/0071888 A1
(43) Pub. Date: Mar. 29, 2007

(54) METHOD AND APPARATUS FOR FORMING DEVICE FEATURES IN AN INTEGRATED ELECTROLESS DEPOSITION SYSTEM

(76) Inventors: Arulkumar Shanmugasundram, Sunnyvale, CA (US); Timothy Weidman, Sunnyvale, CA (US)

Correspondence Address: PATTERSON & SHERIDAN, LLP, 3040 POST OAK BOULEVARD, SUITE 1500, HOUSTON, TX, 77056, US

(21) Appl. No.: 11/534,175

(22) Filed: Sep. 21, 2006

Related U.S. Application Data
(60) Provisional application No. 60/719,440, filed on Sep. 21, 2005.

(51) Int. Cl. H05K 3/00; B05D 3/00; B05D 1/18; C23F 1/00

(52) U.S. Cl. 427/97.7; 427/437; 427/443.1; 427/299; 156/345.31

(57) ABSTRACT

Embodiments of the invention generally provide a cluster tool that is configured to electrolessly fill features formed on a substrate. More particularly, embodiments of the invention are used to integrate the filling of an interconnect or contact level feature using an electroless fill process and material removal steps. A typical sequence for forming an interconnect includes depositing one or more non-conductive layers, etching at least one of the layer(s) to form one or more features therein, depositing a barrier layer in the feature(s) and depositing one or more conductive layers, such as copper, to fill the feature.

### CROSS-REFERENCE TO RELATED APPLICATIONS

This application claims benefit of U.S. Provisional Patent Application Ser. No. 60/719,440, filed Sep. 21, 2005, which is herein incorporated by reference.

### BACKGROUND OF THE INVENTION

1. Field of the Invention

Embodiments of the invention generally relate to a method and apparatus for depositing materials within a feature using an integrated electroless deposition system.

2. Description of the Related Art

Reliably producing nanometer-sized features is one of the key technologies for the next generation of very large scale integration (VLSI) and ultra large scale integration (ULSI) of semiconductor devices. However, as the fringes of circuit technology are pressed, the shrinking dimensions of interconnects in VLSI and ULSI technology have placed additional demands on the processing capabilities. Contact metallization and multilevel interconnect metallization lie at the heart of this technology require precise processing of high aspect ratio features, such as contacts, vias and other interconnects. Reliable formation of these features is very important to VLSI and ULSI success and to the continued effort to increase circuit density and quality of individual substrates.

As circuit densities increase, the widths of vias, apertures, trenches, contacts and other features, as well as the dielectric materials between them, decrease to nanometer dimensions, whereas the thickness of the dielectric layers remains substantially constant, with the result that the aspect ratios for the features, i.e., their height divided by width, increases. Many traditional deposition processes have difficulty filling nanometer-sized structures where the aspect ratio exceeds 4:1, and particularly where the aspect ratio exceeds 10:1. Therefore, there is a great amount of ongoing effort being directed at the formation of substantially void-free, nanometer-sized features having high aspect ratios.

Currently, copper and copper alloys have become the metals of choice for nanometer-sized interconnect technology because copper has a lower electrical resistivity than aluminum, (about 1.7 μΩ-cm compared to about 3.1 μΩ-cm for aluminum), a higher current carrying capacity, and significantly higher electromigration resistance. These characteristics are important for supporting the higher current densities experienced at high levels of integration and increased device speed. Further, copper has a good thermal conductivity and is available in a highly pure state.

Electroless deposition involves an autocatalyzed chemical deposition process that does not require an applied current to induce chemical reduction. An electroless deposition process typically involves exposing a substrate to a solution by immersing the substrate in a bath or by spraying the solution over the substrate. An electroless deposition process of a material within nanotechnology requires a surface capable of electron transfer for nucleation of the material to occur over the surface, such as a catalytic seed layer. Non-metal surfaces and oxidized surfaces are examples of surfaces which cannot participate in electron transfer. Barrier layers comprising tantalum, tantalum nitride, titanium and titanium nitride are poor surfaces for nucleation of a subsequently electrolessly deposited material layer since native oxides of these barrier layer materials are easily formed. Typically, an electroless deposition process utilizes a seed layer as both a catalytic surface as well as an adhesion surface. A seed layer may serve as a surface capable of electron transfer during an electroless deposition process to deposit the electroless layer. However, if there are discontinuities in the seed layer across the surface, then a subsequently deposited layer may not form uniformly cover the seed layer. Also, a seed layer functions as an adhesion layer to the underlying barrier layer or contact surface. For example, an electroless layer deposited on a tantalum nitride barrier layer without an intermediate adhesion seed layer is easily peeled from a substrate surface during a standard tape test.

To form typical contact and via level device features requires the use of multiple systems that are adapted to perform many different processes, which requires a large outlay of money to buy these tools and provide a clean room space to perform these processes. In one example, a process used to fill a device feature formed on the substrate after conventional lithographic and etching techniques have been performed on the substrate, include: 1) depositing a barrier layer in a PVD and/or ALD cluster tool, 2) depositing a seed layer over the barrier layer in the same or different cluster tool, 3) filling a feature in an electrochemical plating cell or performing a CVD fill process in another cluster tool, and 4) chemical mechanical polishing (CMP) of the deposited layer on the field region of the substrate in another cluster tool. The cost of ownership, which is affected by the cost of consumables used to keep each of these cluster tools running and the semiconductor fab space used to house all of these cluster tools, is very expensive for this process sequence, thus making it less competitive. Also, one challenge is to fill very small features of varying depths and widths using this type of process sequence. During typical PVD type device fabrication processes, the PVD deposited material will form regions that overhang the opening of the small features, which can hinder or prevent good gap fill of these features. Further, the cost of consumables used to complete this process sequence, particularly during planarization processes, is high due to the amount of copper that needs to be removed during these steps.

Therefore, there exists a need to reliably fill a feature on a substrate that can be free of defects and can reduce the overall production cost to form these desirable devices.

### SUMMARY OF THE INVENTION

The present invention generally provides a method of processing a substrate in a substrate processing platform, comprising removing a portion of a layer formed on a surface of substrate using a material removal process, and filing a feature formed on the substrate using an electroless deposition process after removing the portion of the layer formed on the surface of the substrate.

Embodiments of the invention may further provide a method of processing a substrate in a substrate processing platform, comprising filing one or more recesses formed on a surface of the substrate with an electrolessly deposited metal layer, and inhibiting the growth of the electrolessly deposited metal layer generally above the top of the recesses formed in the surface of the substrate using a first electrode, a counter electrode and a power supply that is adapted to bias the first electrode relative to the counter electrode, wherein the first electrode is in electrical communication with at least a portion of the metal layer during at least a portion of the electroless deposition process.

Embodiments of the invention may further provide a cluster tool that is adapted to fill a substrate feature on a surface of a substrate, comprising at least one material removal chamber that is adapted to preferentially remove a metal layer from a field region rather than one or more recessed features formed on the surface of a substrate, and at least one electroless plating cell that is adapted to deposit an electrolessly deposited layer on a surface of the substrate.

Embodiments of the invention may further provide a cluster tool that is adapted to fill a substrate feature on a surface of a substrate, comprising at least one electroless plating cell that is adapted to deposit an electrolessly deposited layer on a surface of the substrate and preferentially inhibit growth the electrolessly deposited layer on a field region on the surface of a substrate, and at least one cleaning module.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a transferring sequence according to one embodiment described herein.

FIGS. 2A-2F illustrate schematic cross-sectional views of an integrated circuit fabrication sequence formed by a process described herein.

FIG. 3 illustrates a process sequence according to one embodiment described herein.

FIG. 4 is a schematic plan view of an exemplary deposition system.

FIGS. 5A-5B illustrate a side cross-sectional view of an electroless processing chamber according to one embodiment described herein.

FIGS. 6A-6B illustrate a side cross-sectional view of an electroless processing chamber according to one embodiment described herein.

For clarity, identical reference numerals have been used, where applicable, to designate identical elements that are common between figures.

### DETAILED DESCRIPTION

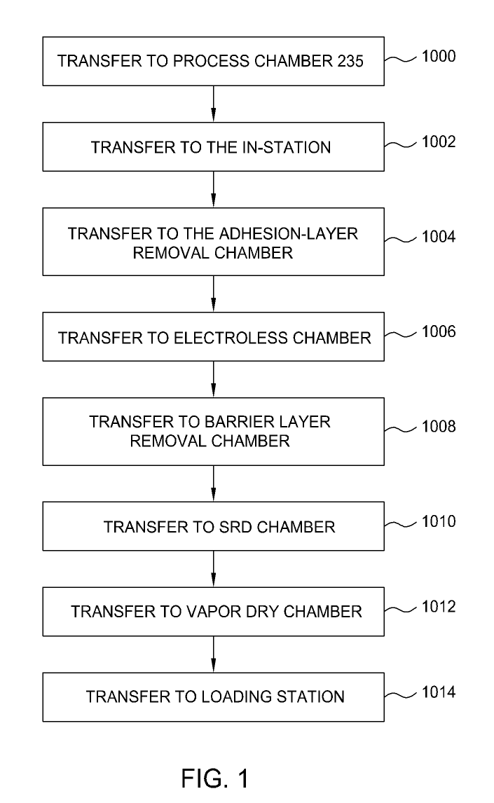

Embodiments of the invention generally provide a cluster tool that is configured to fill features formed on a substrate. An example of a typical substrate transferring sequence for a hybrid electroless/material removal platform is illustrated in FIG. 1, which is discussed below. More particularly, embodiments of the invention allow for the filling of interconnect or contact level features using one or more electroless fill process steps. A typical sequence for forming an interconnect includes depositing one or more non-conductive layers, etching at least one of the layer(s) to form one or more features therein, depositing a barrier layer in the feature(s) and depositing one or more conductive layers, such as copper, to fill the feature.

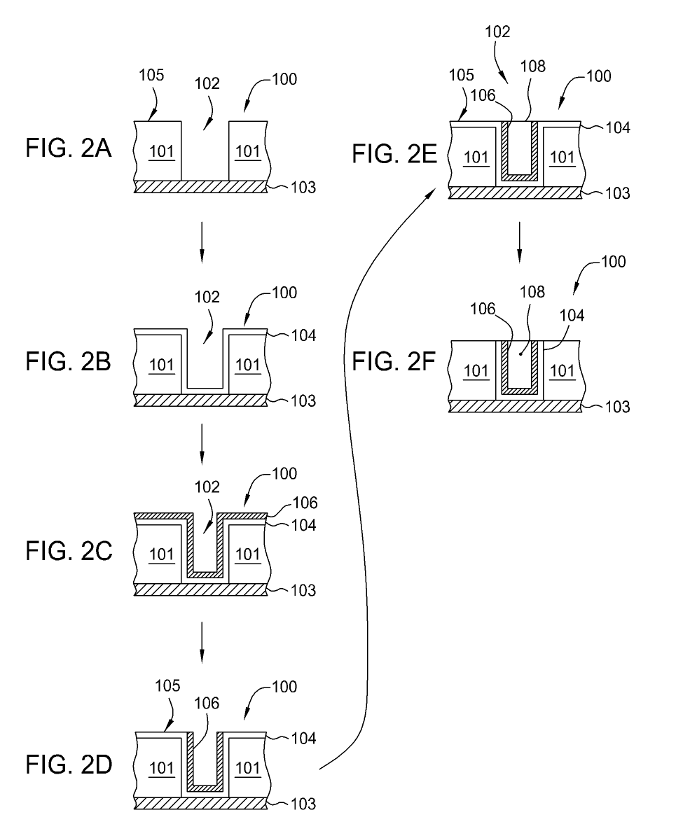

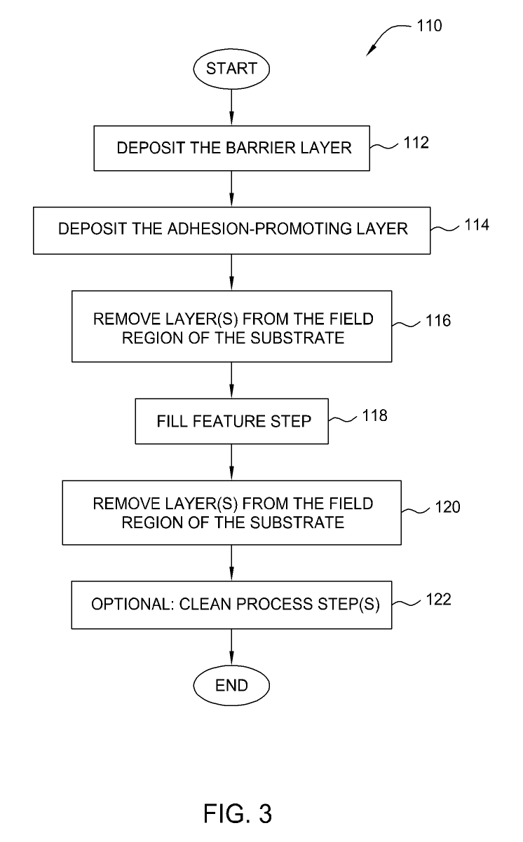

FIGS. 2A-2F illustrate a cross-sectional view of a feature 102 as the various processing steps of a process sequence 110 (FIG. 3) are performed on a substrate 100. FIG. 2A illustrates a cross-sectional view of substrate 100 having a field region 105 and a feature 102 formed into a dielectric layer 101 on the surface of the substrate 100. Substrate 100 may comprise a semiconductor material such as, for example, silicon, germanium, or silicon germanium, for example. The dielectric layer 101 may be an insulating material, such as silicon dioxide, silicon nitride, SOI, silicon oxynitride and/or carbon-doped silicon oxides, such as SiOₓC_{y}, for example, BLACK DIAMOND™ low-k dielectric, available from Applied Materials, Inc., located in Santa Clara, Calif. Feature 102 may be formed in substrate 100 using conventional lithography and etching techniques to expose a layer 103. In general, if the feature 102 is formed at the contact level the layer 103 may be a heavily doped silicon material or a metal silicide layer. If the feature 102 is formed in the interconnect levels (e.g., M1 and above) the layer 103 may contain copper, tungsten, aluminum, nickel, titanium, tantalum, cobalt or alloys thereof.

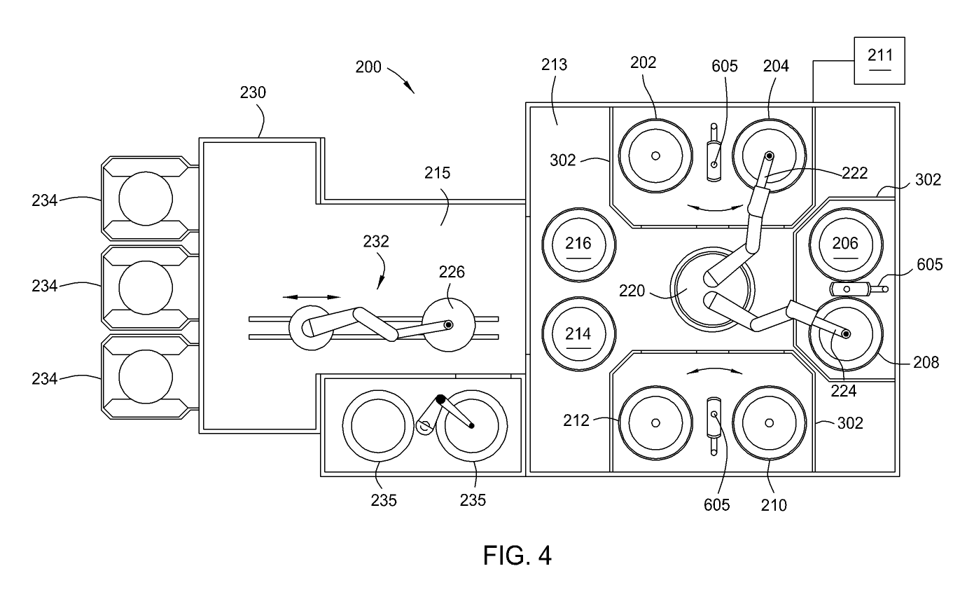

To prevent copper diffusion into dielectric layer 101, barrier layer 104 may be formed on the dielectric layer 101 and in feature 102 (step 112 in FIG. 3), as depicted in FIG. 2B. Barrier layer 104 may be formed using a suitable deposition process including atomic layer deposition (ALD), chemical vapor deposition (CVD), physical vapor deposition (PVD) or combinations thereof. In one embodiment, barrier layer 104 may be formed by a chamber of the cluster tool 200 (FIG. 4) discussed below. In one aspect, the substrate may be placed into a plasma enhanced ALD (PE-ALD), a plasma enhanced CVD (PE-CVD) or high density plasma CVD (HDP-CVD) chamber, such as the ULTIMA HDP-CVD™, Centura iSprint™ or Endura iLB™ systems, available from Applied Materials Inc., located in Santa Clara, Calif.

In one embodiment, where the feature 102 is formed at the contact level on the substrate 100, the barrier layer 104 may performed using a physical vapor deposition (PVD), chemical vapor deposition (CVD) or atomic layer deposition (ALD) deposition process. The barrier layer 104 in this case may be a single deposited layer, or multiple deposited layers, containing ruthenium (Ru), titanium (Ti), titanium nitride (TiN), tungsten (W), tungsten nitride (WN), Tantalum (Ta), tantalum nitride (TaN) or other alloy containing these materials. In one aspect, the single deposited layer or multiple deposited layer stack may contain a Blok™ layer that generally containing SiCN, which is deposited using a CVD process. In one aspect, the multiple deposited layer stack may contain a first layer that is titanium (Ti) and a second layer, which is deposited on the first layer, containing titanium nitride (TiN), tungsten nitride (WN), or tantalum nitride (TaN). In another aspect, the multiple deposited layer stack may contain a first layer that is titanium (Ti), a second layer, which is deposited on the first layer, containing titanium nitride (TiN), tungsten nitride (WN), or tantalum nitride (TaN), and a third layer that may contain titanium (Ti), tantalum (Ta) or tungsten (W) to help promote adhesion. In yet another aspect, the multiple deposited layer stack may have a first layer that contains tantalum (e.g., Ta, TaN) and a second layer that contains copper (Cu).

In one embodiment, where the feature 102 is formed in an interconnect level on the substrate 100 the barrier layer 104 may performed using a physical vapor deposition (PVD), chemical vapor deposition (CVD), or atomic layer deposition (ALD) process. The barrier layer 104 in this case may be a single layer or multiple layer stack containing ruthenium (Ru), titanium (Ti), titanium nitride (TiN), tungsten (W), tungsten nitride (WN), Tantalum (Ta), tantalum nitride (TaN) or other alloy containing these materials. In one aspect, the multiple layer stack may contain a Blok™ layer containing SiCN, which is deposited using a CVD process, over a metal containing barrier layer. In one aspect, the multiple deposited layer stack may contain a first layer that is titanium (Ti) and a second layer, which is deposited on the first layer, containing titanium nitride (TiN), tungsten nitride (WN), or tantalum nitride (TaN). In yet another aspect, the multiple deposited layer stack may have a first layer that contains tantalum (e.g., Ta, TaN) and a second layer that contains copper (Cu). In one aspect, the deposited barrier layer 104 may be about 10 to about 250 Angstroms (Å) thick.

The next step 114, illustrated in FIGS. 2C and 3, includes the deposition of an adhesion-promoting layer 106. To form an adhesion-promoting layer 106, the layer may be deposited on the barrier layer 104 using a physical vapor deposition (PVD), chemical vapor deposition (CVD), electroless deposition or atomic layer deposition (ALD) deposition processes. In one embodiment, the adhesion-promoting layer 106 deposition process may be conducted in the same deposition chamber as the barrier layer deposition process, described above. In one aspect, the adhesion-promoting layer 106 may be a copper (Cu) layer, a ruthenium (Ru) layer, a palladium (Pd) layer, a nickel (Ni) layer, a cobalt (Co) layer, or a layer that is an alloy containing one or more of these elements. In one aspect, the deposited adhesion-promoting layer 106 is about 10 to about 250 Angstroms (Å) thick.

The next step 116, illustrated in FIGS. 2D and 3, includes the removal of a portion of the adhesion-promoting layer 106 from the field region 105 by use of a material removal process, or planarization process, such as an electrochemical process or chemical mechanical polishing process (CMP). The removal of the adhesion-promoting layer 106 is generally performed to limit the growth of subsequently deposited layers on the field region 105 of the substrate 100. It should be noted that growth of the subsequent electrolessly deposited layers on the exposed feature 102 will generally be minimal, since typical barrier layers readily oxidize and thus will generally not participate in the subsequent electroless deposition process(es).

In one aspect, the removal of a portion of the adhesion-promoting layer 106 during the material removal process is performed by use of a planarization process which should be broadly construed and includes, but is not limited to, planarizing a substrate by the application of chemical, mechanical or electrochemical activity. In one aspect, the removal of a portion of the adhesion-promoting layer 106 during the material removal process is performed by use of an electropolishing process which should be broadly construed and includes, but is not limited to, planarizing a substrate by the application of electrochemical activity. In another aspect, the removal of a portion of the adhesion-promoting layer 106 during the material removal process is performed by use of a chemical polishing which is broadly defined, but is not limited to, planarizing a substrate surface using chemical activity. In another aspect, the removal of a portion of the adhesion-promoting layer 106 during the material removal process is performed by use of a CMP process which is broadly construed and includes, but is not limited to, planarizing a substrate by the application of mechanical activity (e.g., use of an abrasive medium) and chemical activity, or a combination of chemical and mechanical activity.

In one aspect, the electrochemical process used to remove a portion of the adhesion-promoting layer 106 is an electrochemical mechanical polishing (ECMP) process which is broadly construed and includes, but is not limited to, planarizing a substrate by the application of electrochemical activity, mechanical activity, chemical activity, or a combination of electrochemical, chemical, and mechanical activity to remove a material from a substrate surface. In one aspect, an ECMP processes is preferred since the material is generally selectively removed from the field region 105 of the substrate 100, rather than from the feature 102. The need for selective removal can be critical where the thickness of the adhesion-promoting layer 106 is rather thin, such as about 10 to about 250 Angstroms (Å). In one aspect, the ECMP process is performed in a Reflexion LK Ecmp™ processing system, available from Applied Materials Inc., located in Santa Clara, Calif. An ECMP chamber and chemistry that may be adapted to perform various aspects of the invention described herein is further described in U.S. patent application Ser. No. 10/456,220, filed Jun. 6, 2003 and U.S. patent application Ser. No. 11/123,274, filed May 5, 2005, which are both incorporated by reference in their entirety to the extent not inconsistent with the claimed aspects of the invention.

In one embodiment of the process sequence 110, the process step 116 is adapted to remove the adhesion-promoting layer 106 and barrier layer 104 from the field region 105 by use of a material removal process, such as an electropolishing process, a chemical polishing process, a CMP process and/or an ECMP process as discussed above.

In one embodiment of the process sequence 110, subsequent to step 116 and prior to step 118, a clean process, such as a megasonic clean process or brush clean process may be performed to remove any material trapped in the features 102.

The next step 118, illustrated in FIGS. 2E and 3, includes the filling of the feature 102 with a metal layer 108 by use of electroless deposition process. In one aspect, the feature is preferentially filled from the bottom of the feature 102 until the layer is about level with the field region 105 (e.g., bottom up fill). In one aspect, the metal layer 108 may be a copper (Cu) layer, a cobalt (Co) layer, a nickel (Ni) layer, or a layer that is an alloy containing one or more of these elements. In one aspect, the feature is filed using a multilayer fill process in which two or more layers are sequentially deposited to fill the feature. An exemplary electroless fill processes and electroless chemistries that may be adapted to perform various aspects of the invention described herein is further described in U.S. Provisional Patent Application Ser. No. 60/709,564, filed Aug. 19, 2005 [APPM 9916L05], U.S. patent application Ser. No. 11/385,290, filed Mar. 20, 2006 [APPM 9916], U.S. patent application Ser. No. 11/385,037 [APPM 9920], filed Mar. 20, 2006, U.S. patent application Ser. No. 11/385,344 [APPM 9916.03], filed Mar. 20, 2006, and U.S. patent application Ser. No. 11/385,038 [APPM 9920.02], filed Mar. 20, 2006, which are all incorporated by reference in their entirety to the extent not inconsistent with the claimed aspects of the invention. In general, the metal layer 108 may be electrolessly deposited using an electroless deposition solution that contains one or more metal ion sources and a reducing agent that allows the deposition of a layer that contains one or more metals. In one aspect, one of the metals ions is a copper ion and the other metal ion(s) are a metal selected from a group consisting of aluminum (Al), indium (In), molybdenum (Mo), tungsten (W), manganese (Mn), cobalt (Co), tin (Sn), nickel (Ni), magnesium (Mg), rhenium (Rh), beryllium (Be), phosphorus (P), boron (B), gallium (Ga), or ruthenium (Ru). In one aspect, a metal alloying element that is more electropositive than copper may be beneficial to improve the oxidation resistance and corrosion resistance of the deposited film.

In one aspect, the metal layer 108 is deposited by an electroless deposition process to fill feature 102 from the bottom-up. Features 102 are filled with metal material while avoiding defects (e.g., seams, voids or gaps) within metal layer 108. The bottom-up fill electroless deposition process utilizes an electroless solution containing a metal ion source and at least one additive, such as an accelerator, a suppressor, a leveler or combinations thereof. FIG. 2E illustrates metal layer 108 deposited over the surface of feature 102. In one aspect, the metal layer 108 is a copper-containing layer is formed from copper or a copper alloy. An exemplary chemistry and method for performing a bottom fill process that may be adapted to perform various aspects of the invention described herein is further described in U.S. patent application Ser. No. 11/385,344 [APPM 9916.03], filed Mar. 20, 2006, U.S. patent application Ser. No. 11/385,037 [APPM 9920], filed Mar. 20, 2006, and U.S. Provisional Patent Application Ser. No. 60/663,492, filed Mar. 18, 2005, which are incorporated by reference in their entirety to the extent not inconsistent with the claimed aspects of the invention.

In general, levelers within the bottom-up fill electroless solution are used to achieve different deposition thickness as a function of leveler concentration and feature geometry while depositing metal layer 108. The leveler within the electroless deposition solution may have a concentration in a range from about 20 ppb to about 600 ppm, preferably from about 100 ppb to about 100 ppm. Examples of levelers that may be employed in an electroless solution include, but are not limited to alkylpolyimines and organic sulfonates, such as 1-(2-hydroxyethyl)-2-imidazolidinethione (HIT), 4-mercaptopyridine, 2-mercaptothiazoline, ethylene thiourea, thiourea, or derivatives thereof.

The electroless deposition solution may contain brighteners or accelerators and suppressors as alternative additives to provide further control of the deposition process. The role of accelerators is to enhance the growth of the metal layer 108 that is in contact with the bottom-up electroless solution. The accelerator within the electroless deposition solution has a concentration in a range from about 20 ppb to about 600 ppm, preferably from about 100 ppb to about 100 ppm. Accelerators that are useful in an electroless solution for depositing metal layer 108 may include sulfur-based compounds such as bis(3-sulfopropyl) disulfide (SPS), 3-mercapto-1-propane sulfonic acid (MPSA), aminoethane sulfonic acids, thiourea, derivatives thereof, and combinations thereof. Suppressors are used to suppress copper deposition by initially adsorbing onto underlying catalytic surfaces (e.g., adhesion-promoting layer 106) and therefore blocking access to the catalyst of the reaction. Suppressors generally may include polyethylene glycol (PEG), polypropylene glycol (PPG), polyoxyethylene-polyoxypropylene copolymer (POCP), benzotriazole (BTA), dipyridyl, dimethyl dipyridyl, derivatives thereof, or combinations thereof. The suppressor within the electroless deposition solution has a concentration in a range from about 20 ppb to about 600 ppm, preferably from about 100 ppb to about 100 ppm.

In one embodiment, the metal ion source within the electroless deposition solution may have a concentration in a range from about 5 mM to about 100 mM, preferably from about 25 mM to about 75 mM. In one aspect, the metal ion is a copper ion (e.g., Cu¹⁺ or Cu²⁺) dissolved within the electroless solution to be reduced out as a deposited copper-containing material. Useful copper sources include copper sulfate, copper chloride, copper acetate, copper phosphate, derivatives thereof, hydrates thereof, or combinations thereof. In one aspect, the metal ion is a nickel ion dissolved within the electroless solution to be reduced out as a deposited nickel-containing material. Useful nickel sources include nickel sulfate, nickel chloride, nickel acetate, nickel phosphate, derivatives thereof, hydrates thereof, or combinations thereof.

In another aspect, the metal layer 108 is a cobalt containing layer. In one aspect, the selective deposition process is performed using an electroless deposition process to selectively deposit a layer that contains, for example, a cobalt-tungsten alloy (e.g., CoW, CoWP, CoWB, CoWPB). An example of an electroless solution used to deposit a cobalt-tungsten alloy may contain a cobalt source, a tungsten source, a citrate source, a hypophosphite source, a borane reductant, and other additives. Other electroless deposition solutions that may be used to deposit a cobalt-tungsten alloy are further described in the commonly assigned U.S. patent application Ser. No. 10/967,919, entitled, “Selective Self-initiating Electroless Capping of Copper with Cobalt-containing Alloys,” filed on Oct. 18, 2004, which is incorporated by reference to the extent not inconsistent with the claimed aspects and description herein.

The next step 120, illustrated in FIGS. 2F and 3, includes the removal of the barrier layer 104 from the field region 105 by use of a material removal process, such as an electrochemical process or chemical mechanical polishing process (CMP). If the barrier layer is removed during process step 116 this process step may not be needed and can thus be left out. In one aspect, this process step includes the process of removing any over plating leftover after performing the deposition of the metal layer 108. An ECMP chamber and chemistry that may be used to remove a barrier layer and thus may be adapted to perform various aspects of the invention described herein is further described in U.S. patent application Ser. No. 11/130,032, filed May 16, 2005 and U.S. Provisional Patent Application Ser. No. 60/650,676, filed Feb. 7, 2005, which are both incorporated by reference in their entirety to the extent not inconsistent with the claimed aspects of the invention.

In one aspect, the removal of a portion of the barrier layer 104 is performed by use of an electropolishing process, chemical polishing process, CMP process and/or ECMP process as discussed above in step 116. In one aspect, an ECMP processes is preferred since the material is generally selectively removed from the field region 105 of the substrate 100, rather than from the feature 102. The need for selective removal can be critical where the thickness of the barrier layer 104 is rather thin, such as about 10 to about 250 Angstroms (Å). In one aspect, the ECMP process is performed in a Reflexion LK Ecmp™ processing system, available from Applied Materials Inc., located in Santa Clara, Calif.

In one aspect, a CMP process is used to remove the barrier layer 104. In this configuration it may be desirable to use at least one polishing platen and at least one chemistry to remove the desired layer(s) and prevent scratching.

In one embodiment of the process sequence 110, subsequent to step 120 and prior to step 122, an electroless capping layer deposition process is performed over the filled features 102. In one aspect, the capping layer deposition process is performed using an electroless deposition process to selectively deposit a layer that contains, for example, a cobalt-tungsten alloy (e.g., CoW, CoWP, CoWB, CoWPB). An example of an electroless solution used to deposit a cobalt-tungsten alloy may contain a cobalt source, a tungsten source, a citrate source, a hypophosphite source, a borane reductant, and other additives.

The next step 122, illustrated in FIG. 3, optionally includes the process of cleaning and/or drying the substrate 100 after all the process steps in the process sequence 110 have been performed. The clean step 122 may be performed by applying a clean solution to the substrate structure, scrubbing the surface of the substrate with a brush like material and/or applying sonic energy to the substrate structure to remove any excess material that may be present on the exposed portion of the substrate 100. The use of a brush module to clean a substrate may be especially useful when CMP or ECMP processes are used that contain a slurry component. In one embodiment, the clean solution may include one or more acids (e.g., citric acid). One example of a post-deposition clean solution is an ElectraClean™ solution, available from Applied Materials Inc. of Santa Clara, Calif. or a CX-100 solution available from Wako Chemicals USA, Inc. of Richmond, Va. In one embodiment, the cleaning process, or processes, is performed in a spin rinse dry (SRD) chamber, integrated bevel clean (IBC) chamber, Dessica™ brush clean module, or vapor dry module commonly found in a Reflexion CMPTM system or SlimCell ECP™ system, which are available from available from Applied Materials Inc., located in Santa Clara, Calif. In one example of process step 122, the substrate is cleaned by exposing one or more surfaces of the substrate to a cleaning solution to remove any accumulated material therefrom and then performing a drying process. In one aspect, the cleaning solution is a high resistivity deionized water solution that is delivered to the processing surface of the substrate. One example of an SRD chamber that may be adapted to perform step 122 is further described in the commonly assigned U.S. Pat. No. 6,290,865, which is incorporated by reference herein in its entirety.

In one aspect of process step 122, the bevel edge of the substrate may be cleaned to remove any accumulated material therefrom (often called the edge bead) by providing an etchant solution. One example of an etchant solution includes a solution of sulfuric acid, hydrogen peroxide and deionized water. Another example of an etchant solution further includes HCl and/or nitric acid. One apparatus and method of cleaning the bevel edge, or edge bead removal chamber, is disclosed in U.S. Pat. No. 6,516,815, entitled “Edge Bead Removal/Spin Rinse Dry (EBR/SRD) Module,” which is incorporated by reference to the extent not inconsistent with the present disclosure. Another apparatus and method of cleaning the bevel edge is disclosed in U.S. patent application Ser. No. 09/785,815, entitled “Integrated Semiconductor Substrate Bevel Cleaning Apparatus and Method,” which is incorporated by reference in its entirety to the extent not inconsistent with the present disclosure.

In another aspect of process step 122, a vapor drying step may be performed by itself or in conjunction with the SRD and/or bevel edge cleaning steps. Vapor drying generally includes introducing a surface tension-reducing volatile compound, such as a volatile organic compound (VOC), to the substrate structure as it is removed from a bath. For example, a VOC may be introduced with a carrier gas (e.g., nitrogen gas) in the vicinity of the liquid adhering to a substrate structure. The introduction of the VOC results in surface tension gradients which cause the liquid to flow off of the substrate, leaving it dry. In one embodiment, the VOC is isopropyl alcohol (IPA). In one embodiment, the liquid is deionized water (i.e., DI Water). In other embodiments, the VOC may be other alcohols, ketones, ethers, or other suitable compounds. Examples of exemplary vapor drying processes are further described in the commonly assigned U.S. Pat. No. 6,328,814, filed Mar. 26, 1999 [AMAT No. 2894/CMP/RKK] and U.S. patent application Ser. No. 10/737,732, entitled “Scrubber With Integrated Vertical Marangoni Drying”, filed Dec. 16, 2003, which is incorporated by reference in its entirety to the extent not inconsistent with the present disclosure.

General Cluster Tool Description

Various embodiments of a cluster tool and process chambers that may be adapted to perform the at least two of the process steps described above in FIGS. 2A-F and 3 is described below. In one embodiment, the cluster tool generally contains a wet processing platform in communication with a substrate loading area and together with the loading area, comprises a substrate plating system. The loading area, or “dry side”, is generally configured to receive substrate-containing cassettes and transfer substrates received from the cassettes to the wet processing platform for wet processing. The loading area typically includes “dry side” processing chambers for treatment of substrates before and/or after wet processing, such as barrier layer deposition chambers and anneal chambers. The dry side may also contain a robot configured to transfer substrates between the cassettes, the wet processing platform, and the dry side processing chambers. The wet processing platform generally includes at least one substrate transfer robot and a plurality of substrate processing chambers, e.g., electroless plating cells, ECMP chambers, ECP cells, IBC chambers, SRD chambers, etc. The various embodiments may include different combinations of wet and dry substrate-processing chambers. In one aspect, the cluster tool will allow for pre-treatment of a dry substrate, such as barrier layer deposition (e.g., PVD, ALD or CVD chambers), wet processing of the substrate, such as adhesion-layer deposition, electrochemical and/or electroless gap fill, and surface and/or bevel cleaning and drying, and in some cases post-deposition processing, such as anneal.

FIG. 4 illustrates an exemplary electroless cluster tool 200. Cluster tool 200 includes a factory interface 230 that includes a plurality of substrate loading stations 234 configured to interface with and retain substrate containing cassettes (hereafter referred to as cassettes). A factory interface robot 232 is positioned in the factory interface 230 and is configured to access and transfer substrates 226 into and out of the cassettes positioned on the loading stations 234. The robot 232 also extends into a link tunnel 215 that connects the factory interface 230 to a wet processing platform (i.e., platform 213). The position of robot 232 allows for access to loading stations 234 to retrieve substrates therefrom, and to then deliver the substrates 226 to an in-station 972 (not shown in FIG. 4 for clarity) positioned on the platform 213 and typically located above processing cell location 214. Similarly, robot 232 may be used to transfer a substrate 226 into or out of processing cell locations 214 and 216 or station 235. Station 235 may include one or more stacked dry process chambers, such as anneal, barrier layer deposition, adhesion-layer deposition or even dry etch chambers. Barrier layer and adhesion-layer deposition take place prior to wet processing of a substrate and the annealing process typically takes place after wet processing. An anneal chamber that may be adapted to perform various aspects of the invention described herein is further described in U.S. patent application Ser. No. 10/996,342, filed Nov. 22, 2004, which is incorporated by reference in its entirety to the extent not inconsistent with the claimed aspects of the invention. When removing substrate 226 from locations 214, 216, or 235, robot 232 may then deliver the clean, dry substrate 226 back to one of the cassettes positioned on the loading stations 234 for removal from cluster tool 200.

Wet processing platform 213, also referred to as the mainframe, includes a centrally positioned mainframe robot 220. Mainframe robot 220 generally includes one or more blades 222 and 224 configured to support and transfer substrates. Additionally, mainframe robot 220 and the accompanying blades 222 and 224 are generally configured to independently extend, rotate, pivot, and vertically move so that the mainframe robot 220 may simultaneously insert and remove substrates to/from the plurality of processing cell locations 202, 204, 206, 208, 210, 212, 214 or 216 positioned on platform 213. Similarly, factory interface robot 232 also includes the ability to rotate, extend, pivot, and vertically move its substrate support blade, while also allowing for linear travel along the robot track 250 that extends from the factory interface 230 to the platform 213.

Generally, the processing cell locations 202, 204, 206, 208, 210, 212, 214, or 216 may be any of a number of processing chambers utilized in a substrate processing system. More particularly, the processing chambers on the integrated wet processing platform may be configured as material removal process chambers (e.g., ECMP cells, CMP platen, electropolishing cells), rinsing chambers, IBC chambers, SRD chambers, substrate surface cleaning chambers (which collectively includes cleaning, rinsing, and etching chambers), electroless plating chambers (which includes pre- and post-clean chambers, electroless activation chambers, electroless deposition chambers, etc.), brush box chambers and vapor drier chambers. Each of the various configurations of the wet processing platform and the factory interface will be discussed below.

Each of the respective processing cell locations 202, 204, 206, 208, 210, 212, 214 and 216 and robots 220 and 232 are generally in communication with a process controller 211, which may be a microprocessor-based control system configured to receive inputs from both a user and/or various sensors positioned on the cluster tool 200 and appropriately control the operation of cluster tool 200 in accordance with the inputs and/or a predetermined processing recipe. Additionally, the processing cell locations 202, 204, 206, 208, 210, 212, 214 and 216 are also in communication with a fluid delivery system (not shown) configured to supply the necessary processing fluids to the respective processing cell locations during processing, which is also generally under the control of system controller 211. An exemplary processing fluid delivery system may be found in commonly assigned U.S. patent application Ser. No. 10/438,624, entitled “Multi-Chemistry Electrochemical Processing System,” filed on May 14, 2003, which is hereby incorporated by reference in its entirety to the extent not inconsistent with the present invention.

Cluster Tool Configurations

In an effort to provide a cluster tool that can perform the process described in FIGS. 2A-F and 3, various embodiments of cluster tools may be created. These embodiments are capable of performing one or more of the above processes with high throughput, low defects, minimal oxidation of copper interconnect features and superior adhesion between deposited layers.

A. Cluster Tool Configuration

One embodiment, as illustrated in FIG. 4, of a cluster tool 200 generally includes an electroless plating cell, ECMP processing cell, and an optional clean chamber(s). In one embodiment, the cluster tool 200 contains a CMP type processing chamber. In one aspect, the clean chambers are a bevel clean, vapor dry and/or spin-rinse drying type processing chambers. Optionally, the cluster tool may include an ALD barrier processing chamber and/or adhesion-layer deposition processing chambers prior to performing wet processing. Optionally, it may also include a plasma-enhanced dry etch chamber for removal of native oxide prior to barrier or adhesion-layer deposition. This configuration of plating cluster tool 200 allows the sequential deposition of multiple films on a substrate within a single cluster tool, such as an ALD or CVD barrier layer formed on substrate structures, such as tantalum nitride (TaN), an electroless copper fill layer formed on the substrate structures or a barrier layer, and lastly a clean of the features on the substrate. In one embodiment, the adhesion-layer 106 is a Ruthenium-containing layer deposited without the use of carbon-containing precursors, using a process described in the commonly assigned U.S. patent application Ser. No. 11/228,425, filed Sep. 15 2005, and U.S. Provisional Patent Application entitled “Patterned Electroless Metallization Processes For Large Area Electronics” [APPM 10254L] by T. Weidman and filed Sep. 8, 2005, which are all herein incorporated by reference. Barrier layer, seed layer and gap fill deposition are ordinarily performed by separate substrate processing systems, increasing total substrate processing time and expense. Also, this configuration of plating cluster tool 200 deposits metal layers with improved electrical properties, better defect performance and greater adhesion than metal layers formed on a substrate via multiple substrate processing systems. The sequential formation of the processes described in FIGS. 2A-F in a controlled environment will result in fewer defects compared to processing substrates in multiple processing systems. Also, the use of ruthenium-containing adhesion-layers can also offer superior adhesion to subsequent metal layers over the prior art. Hence, this configuration provides better device performance, at a lower cost per substrate processed, and the process is less complicated than conventional systems.

B. Description of Cluster Tool Configuration

FIG. 4 illustrates one embodiment of an exemplary cluster tool 200. In this embodiment, station 235 may be configured as an ALD or CVD chamber for the deposition of a barrier layer and/or adhesion-layer prior to wet processing. Referring to FIG. 4, processing locations 214 and 216 may be configured as an interface between wet processing platform 213 and the generally dry processing stations positioned in factory interface 230 of the plating cluster tool 200. As such, substrates are introduced into platform 213 by being placed in a holding location, know as an in-station (not shown) which holds substrates for future wet processing. The in-station is typically located above or below processing stations 214 and 216. In this configuration, the processing stations 214 and 216 may include a vapor dry chamber or SRD chamber that is adapted to perform the final wet processing steps on a substrate before the substrate leaves platform 213. In one aspect, the processing station 214 is an SRD chamber and 216 is a vapor dry chamber that is adapted to perform the final wet processing steps on a substrate before the substrate leaves platform 213. A spin rinse dry (SRD) chamber, integrated bevel clean (IBC) chamber, Desica™ brush clean module, or vapor dry module are commonly found in a Reflexion CMP™ system or SlimCell ECP™ systems which are available from available from Applied Materials Inc., located in Santa Clara, Calif. Examples of exemplary vapor drying processes are further described in the commonly assigned U.S. Pat. No. 6,328,814, filed Mar. 26, 1999 [AMAT No. 2894/CMP/RKK] and U.S. patent application Ser. No. 10/737,732, entitled “Scrubber With Integrated Vertical Marangoni Drying”, filed Dec. 16, 2003, which is incorporated by reference in its entirety to the extent not inconsistent with the present disclosure.

In one embodiment of cluster tool 200, the processing locations 202 and 210 contain electroless plating cells, the processing locations 204 and 212 contain ECMP cells that are adapted to remove adhesion-layer 106, and the processing locations 206 and 208 contain ECMP cells that are adapted to remove the barrier-layer 104. In this configuration the process chemistry used in the ECMP cells that are adapted to the barrier layer 104 and the ECMP cells that are adapted to remove the adhesion-layer 106 may have different chemistries which are used to enhance the removal of the desired type of material. In another embodiment, processing locations 202 and 204, and 210 and 212 are electroless plating twin cells, and locations 206 and 208 are ECMP chambers that are adapted to remove both the adhesion-layer 106 and the barrier-layer 104. In yet another embodiment, processing locations 202, 206, and 210 are electroless plating cell, and processing locations 204, 208 and 212 are ECMP chambers that are adapted to remove both the adhesion-layer 106 and the barrier-layer 104. The configurations of the processing chambers in the various processing locations 202, 204, 206, 208, 210 and 212 may be rearranged without affecting the functionality of the invention and are defined above only for purposes of description. In one embodiment, between the processing locations 202/204, 210/212, and 206/208 which may be contained by a processing enclosure 302, a substrate transfer shuttle 605 that is adapted to transfer substrates between the first and second processing stations inside each enclosure 302. Exemplary electroless plating cells are further described in U.S. patent application Ser. No. 10/059,572, filed Jan. 28, 2002 [AMAT No. 5840.03], U.S. patent application Ser. No. 10/996,342, filed Nov. 22, 2004, and U.S. patent application Ser. No. 11/192,993 [APPM 8707.P1], filed Jul. 29, 2005 which is incorporated by reference in its entirety to the extent not inconsistent with the present disclosure. An ECMP chamber that may be adapted to perform various aspects of the invention described herein is further described in U.S. patent application Ser. No. 10/456,220, filed Jun. 6, 2003 and U.S. patent application Ser. No. 11/123,274, filed May 5, 2005, which are both incorporated by reference in their entirety to the extent not inconsistent with the claimed aspects of the invention.

Process Sequence

An example of a typical substrate transferring sequence for a hybrid electroless/material removal platform is illustrated in FIG. 1 which is used to complete the processing sequence illustrated in the flow chart illustrated in FIG. 3. As noted above, in one exemplary hybrid electroless/electrochemical plating platform configuration, which is used here to illustrate one embodiment of the present invention, the cluster tool may contain electroless plating cells in processing locations 202 and 210, a adhesion-layer removal ECMP cells in the processing locations 204 and 212, a barrier layer ECMP (or CMP) processing cell in processing locations 206 and 208, an SRD in the processing location 214, and a vapor dry chamber in the processing location 216. The vapor dry chamber in the processing location 216 is adapted to perform the final wet processing steps on a substrate before the substrate leaves platform 213 (FIG. 4). Optionally, station 235 is configured as a barrier layer ALD/CVD chamber.

In step 1000, an optional substrate pre-treatment step is performed, where with a barrier layer (element 104 in FIGS. 2B-E) and an adhesion-promoting layer (element 106 in FIGS. 2B-E) are deposited on the substrate in station 235 prior to wet processing. If it is not desirable to form the barrier layer and an adhesion-layer in the cluster tool 200, then these steps may be performed in other cluster tools, such as the ULTIMA HDP-CVD™, Centura iSprint™ or Endura iLB™ systems, available from Applied Materials Inc., located in Santa Clara, Calif.

In step 1002, factory interface robot 232, also known as the “dry” robot, removes the substrate from the station 235 and places the substrate at the in-station associated with processing location 214 or 216.

In step 1004, mainframe robot 220, also known as the “wet” robot, transfers the substrate to a process chamber positioned in one of the locations 204 or 212, where an adhesion-layer material removal process (e.g., planarization process) is preformed, such as a CMP or ECMP process.

In one embodiment of the invention, subsequent to the planarization process a clean process, such as a megasonic clean process or brush clean process may be performed to remove any material trapped in the features.

In step 1006, in one embodiment, the substrate is transferred between processing locations 204 or 212 to processing locations 202 or 210, respectively, via use of an internal shuttle transfer 605. In the processing locations 202 or 210, an electroless deposition process (step 118) is performed to fill the feature. In one aspect, the electroless deposition requires an activation type process (e.g., preparatory cleaning, activation and post-activation clean steps) to be performed, and then an electroless plating step may be performed. In one aspect, the electroless deposition requires only that an electroless plating step to be performed. In another aspect of step 1006, not shown in FIG. 1, the mainframe robot 220 is used to transfer the substrate between the processing locations 204 and 202, or 212 and 210.

In step 1008, the mainframe robot 220 transfers a substrate to one of the processing station 206 or 208, where the barrier CMP process is optionally performed. In one aspect, a barrier ECMP process is optionally performed.

In one embodiment of the invention, subsequent to the barrier CMP (or ECMP) process a clean process, such as a megasonic clean process or brush clean process may be performed to remove any material trapped in the features.

In step 1010, the mainframe robot 220 transfers a substrate to the processing location 214 where an SRD process is performed. A description of an exemplary SRD chamber that may be used in embodiments of the invention may be found in commonly assigned U.S. application Ser. No. 10/616,284 entitled “Multi-Chemistry Plating System,” filed on Jul. 8, 2004, which is hereby incorporated by reference in its entirety to the extent not inconsistent with the present invention. [7669.P1]

In step 1012, the mainframe robot 220 transfers a substrate from the processing location 214 to the processing location 216 where a vapor dry process is performed. In one aspect, either step 1010 or step 1012 may be removed to reduce the complexity of the device fabrication and transferring process.

In step 1014, after the vapor dry process is complete, factory interface robot 232 removes the substrate from the vapor dry chamber, which is in the processing location 216, and the platform 213 and places them in the substrate loading stations 234.

Electroless Bottom-Up Fill Chamber.

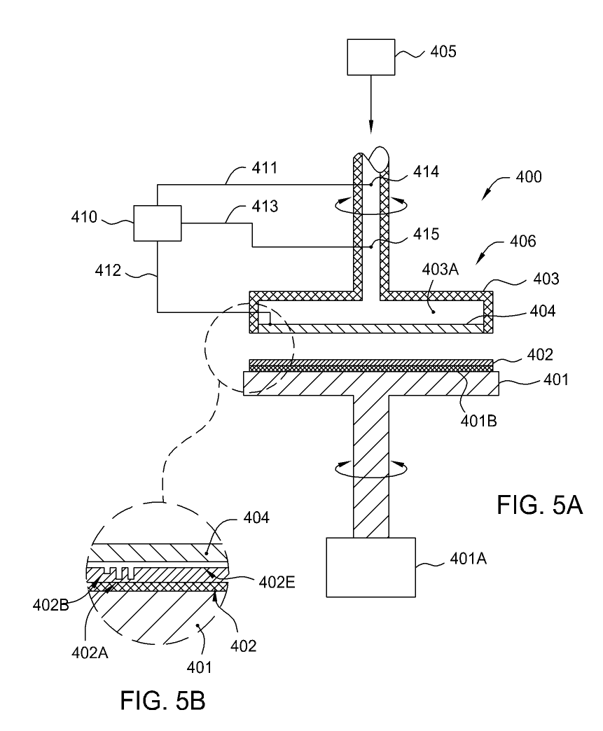

In one embodiment of the invention, an electroless plating chamber 400 is configured to improve the bottom-up fill capability and reduce common defects found during the filling of features of different depths and shapes. FIGS. 5A and 5B illustrate one embodiment of an electroless plating chamber 400 that may be adapted to perform aspects described herein. In general, the electroless plating chamber 400 contains a substrate support 401 and an electrode assembly 406, which is positioned opposing the processing surface 402E (FIG. 5B) of the substrate 402 positioned on the substrate support 401. The substrate support 401 generally contains a substrate receiving surface 401B and lift/rotation assembly 401A. In one aspect, the lift/rotation assembly 401A is adapted to raise and lower and rotate the substrate support 401 relative to the electrode assembly 406. In another aspect, the electrode assembly 406 is adapted to be raised and lowered and/or rotated relative to the substrate 402. In yet another aspect, the substrate 402 or the flexible electrode 404 and/or the substrate support 401 may be rotated or oscillated. While FIGS. 5A and 5B tend to illustrate an electroless plating chamber 400 that is in a face-up orientation, this configuration is not intended to limit the scope of the invention described herein.

In one aspect of the electroless plating chamber 400, the electrode assembly 406 generally contains a flexible electrode 404, an electrode support 403, and a power supply 410. The power supply 410 is generally adapted to bias the flexible electrode relative to the counter electrode 414. The power supply 410 is connected to the flexible electrode 404 using an electrical connection 412, the counter electrode using the electrical connection 411 and an optional reference electrode 415 using the electrical connection 413. In one aspect, the flexible electrode 404 is a conductive porous electrode that is adapted to allow the electroless plating solution delivered from the source 405 through the flexible electrode 404 and to the processing surface 402E of the substrate 402.

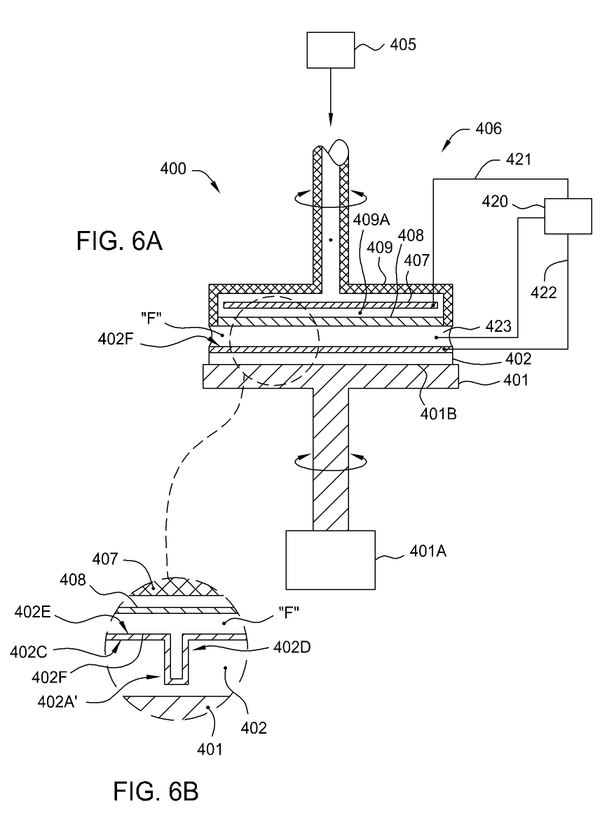

In another aspect, the flexible electrode 404 contains an biasing electrode (not shown) and an ionic membrane, such as a Nafion™ membrane, that allows certain ions to pass through the flexible electrode 404 assembly but keeps the fluid delivered from source 405 separated from the electroless deposition fluid that is in contact with the processing surface 402E of the substrate 402. In this configuration, the fluid in contact with the processing surface 402E of the substrate 402 can be delivered from a separate fluid source (not shown) that is in fluid communication with the processing surface 402E. In this configuration the biasing electrode (not shown), such as a metal rod or wire mesh (e.g., platinum, titanium), is positioned in the fluid volume 403A (e.g., similar to item # 407 in FIG. 6A) formed between the electrode support 403 and the flexible electrode 404. In one aspect, the substrate 402 or the flexible electrode 404 and/or the substrate support 401 may be rotated or oscillated.

In one aspect, the flexible electrode 404 is constructed from a woven fabric material such as a graphite cloth selected such that is does not exhibit catalytic properties towards the oxidation of the reducing agent utilized in the electroless plating formulation and which is essentially inert towards dissolution in the plating chemistry. The flexible electrode 404 should also generally be inert towards dissolution in the plating chemistry. In one aspect, if the flexible electrode 404 is highly absorbent it will facilitate the efficient retention of a relatively small volume of plating chemistry on the surface of the substrate 402.

The use of the electroless plating chamber 400 is intended to prevent the filling bottom-up growth of shallow features 402B formed on the substrate 402 from covering the opening of the deeper features 402A as the electroless deposition process proceeds towards filling all of the features formed on the processing surface 402E of the substrate 402. In one embodiment, in operation the an electroless deposition fluid is delivered to the fluid volume 403A and processing surface 402E of the substrate 402 and an anodic bias is applied to the flexible electrode 404 relative to the counter electrode 414. The flexible electrode is positioned such that it is either brought into contact or is positioned very close to the processing surface 402E of the substrate 402. Therefore, as the shallow feature 402B is filled with the electroless deposition material the metal layer formed in the shallow feature (e.g., element 108 FIG. 2E) will contact the flexible electrode 404 before the metal layer formed in the deep feature 402A contacts the flexible electrode 404. Contact of a metal layer with the flexible electrode 404 will effectively “siphoning off” electrons liberated by the autocatalytic oxidation of the reducing agent and minimize the deposition over the shallow features 402B and thus allowing the deep features 402A to “catchup.” The applied field on the flexible electrode 404 is adjusted so as to suppress/prevent the deposition of the metal layer contacting the flexible electrode 404. In one aspect, the applied potential is adjusted relative to a reference electrode 415 and the cell completed by a dimensionally stable counter electrode 414 located behind an ion exchange type membrane or effectively “downstream” from the plating region.

In one aspect, the bottom up electoless fill process can be initiated prior to introducing (i.e. lowering to make contact) the flexible electrode 404. In another aspect, the flexible electrode 404 can be present form the beginning and only biased until well after the initiation and substantial filling of the shallow features 402B or fastest growing features has occurred.

This invention has immediate relevance for applications in which contact is being made to a material which is in the field region (e.g., element 105 in FIGS. 2A-F) which is intrinsically catalytically active towards the initiating of an electroless plating chemistry, thereby providing a mechanism for selective bottom up fill and inhibiting the growth that is in contact with the flexible electrode 404.

Second Type of Electroless Process Chamber

In one embodiment, there exists an equally important variation of the electroless chamber 400 in which a conformally deposited adhesion-layer, or barrier layer, which may or may not be electrically conducting, is first removed by an efficient CMP and/or electrochemically assisted striping process from the “field regions” (e.g., item # 402C in FIG. 6) before the initiation of the electroless filling process. In such applications, the process may also require that the conformally deposited adhesion-layer, or barrier layer, be highly electrically resistive or be prone to preferentially dissolution with an electrode (e.g., flexible electrode 404 or electrode 407 (seen below)) during the initiation and growth of the electrolessly deposited layer. In one aspect, the preferentially dissolution may be enhanced due to an application of a high electrical bias or the use of a resistive electroless plating solution. As such it might be applied even to the electroless metal fill of damascene structures initiating on extremely thin ALD like layers without the requirement for an electrically contiguous contact.

In another embodiment, an electroless plating chamber 400 is configured to improve the bottom-up fill capability and reduce common defects found during the filling of features of different depths and shapes. FIG. 6 illustrates one embodiment of an electroless plating chamber 400 that may be adapted to perform aspects described herein. While FIG. 6 tends to illustrate an electroless plating chamber 400 that is in a face-up orientation, this configuration is not intended to limit the scope of the invention described herein. In general, the electroless plating chamber 400 contains a substrate support 401 and an electrode assembly 406, which is positioned opposing the processing surface 402E of the substrate 402 positioned on the substrate support 401. The substrate support 401 generally contains a substrate receiving surface 401 B and lift/rotation assembly 401A. In one aspect, the lift/rotation assembly 401A is adapted to raise and lower and rotate the substrate support 401 relative to the electrode assembly 406.

In one aspect of the electroless plating chamber 400, the electrode assembly 406 generally contains an electrode 407, an electrode support 409, a membrane 408 and a power supply 420. The power supply 420 is generally adapted to bias the electrode 407 relative to a metal layer 402F formed on the processing surface 402E of the substrate 402. The power supply 420 is connected to the electrode 407 using an electrical connection 421, the substrate surface using the electrical connection 422 (e.g., using platinum contacts or other conventional contact designs which are well known in the art) and an optional reference electrode 423 positioned in a fluid layer “F” positioned between the electrode 407 and the metal layer 402F formed on the processing surface 402E.

In one aspect, the electrode 407 is a conductive porous electrode that is adapted to allow the electroless plating solution delivered from the source 405 through the electrode 407 and the membrane 408 to the processing surface 402E of the substrate 402. In another aspect, the membrane 408 is an ionic membrane, such as a Nafion™ membrane, that allows certain ions to pass between the electrode 407 and the metal layer 402F formed on the processing surface 402E. In this aspect, the ionic membrane keeps the fluid delivered from source 405 separated from the electroless deposition fluid layer “F” that is in contact with the processing surface 402E of the substrate 402. In this configuration, the fluid in contact with the processing surface 402E of the substrate 402 can be delivered from a separate fluid source (not shown) that is in fluid communication with the processing surface 402E. In this configuration the electrode 407, is positioned in the fluid volume 409A formed between the electrode support 409 and the electrode 407. In one aspect, the substrate 402 or the flexible electrode 404 and/or the substrate support 401 may be rotated or oscillated.

In one aspect, the electrode 407 is constructed from a woven fabric material such as a graphite cloth selected such that is does not exhibit catalytic properties towards the oxidation of the reducing agent utilized in the electroless plating formulation and which is essentially inert towards dissolution in the plating chemistry. In one aspect, if the electrode 407 is a metal material such as titanium, platinum, copper, palladium, or other material.

The use of the electroless plating chamber 400 shown in FIG. 6 is intended to minimize the growth of the electrolessly deposited material on the field region 402C (e.g., element 105 in FIGS. 2A-F) of the substrate 402 by preferentially removing the material on the field prior to performing the electroless plating process or by controlling the amount deposited on the field region 402C during the electroless deposition process. In operation the an electroless deposition fluid is delivered to the fluid volume 409A and processing surface 402E of the substrate 402 and a cathodic bias is applied to the electrode 407 relative to the metal layer 402F. In one aspect, the preferentially dissolution from the field region 402C may be enhanced due to an application of a high cathodic electrical bias or the use of a resistive electroless plating solution. As such the bias might be applied even during the electroless metal fill of damascene structures that are initiating on extremely thin ALD like layers without the requirement for an electrically contiguous contact.

In one aspect, a membrane 408 that has a desired abrasive properties (e.g., fixed abrasive CMP pad type materials) is positioned such that it is brought into contact the processing surface 402E of the substrate 402. Therefore, the when the membrane 408 is moved relative to the processing surface 402E of the substrate the electroless deposition material that is being deposited on the field region 402C is continually being removed as the other parts of the feature 402A′ (e.g., element 402D) is being filled with electrolessly deposited material. In one embodiment, the surface of the membrane 408 is made from a conductive medium, such as a conventional conductive pad used in ECMP applications, which is available from Applied Materials Inc., to make contact across the surface of the processing surface 402E.

In one aspect, the field, and/or voltage, applied to the electrode 407 is adjusted so as to suppress/prevent the deposition of the metal on the field region 402C. The applied potential is adjusted relative to the surface of the substrate 402 and the electrode 407 located behind the membrane 408, which is effectively “downstream” from the plating region.

While the foregoing is directed to embodiments of the present invention, other and further embodiments of the invention may be devised without departing from the basic scope thereof, and the scope thereof is determined by the claims that follow.

1. A method of processing a substrate in a substrate processing platform, comprising:
removing a portion of a layer formed on a surface of substrate using a material removal process; and
filing a feature formed on the substrate using an electroless deposition process after removing the portion of the layer formed on the surface of the substrate.

2. The method of claim 1, further comprising:
cleaning the surface of the substrate subsequent to removing the portion of the layer formed on the surface of the substrate and prior to filling the feature, wherein cleaning comprises exposing a surface of a substrate to a liquid or a vapor selected from a group consisting of DI water, isopropyl alcohol, and an etchant solution.

3. The method of claim 2, wherein the cleaning the surface of the substrate comprises vapor drying the substrate in a vapor dry chamber.

4. The method of claim 1, wherein removing a portion of a layer formed on a surface of substrate is performed by use of a process selected from a group consisting of a chemical mechanical polishing process, an electrochemical mechanical polishing process and an electropolishing process.

5. The method of claim 1, wherein the adhesion-layer and barrier layer are removed during the material removal step.

6. The method of claim 1, wherein removing a portion of a layer formed on a surface of substrate comprises:
a first planarization step to remove the adhesion-layer; and
a second planarization step to remove the barrier layer.

7. The method of claim 1, further comprising depositing an electroless capping layer after filling the feature.

8. A method of processing a substrate in a substrate processing platform, comprising:
filing one or more recesses formed on a surface of the substrate with an electrolessly deposited metal layer; and
inhibiting the growth of the electrolessly deposited metal layer generally above the top of the recesses formed in the surface of the substrate using a first electrode, a counter electrode and a power supply that is adapted to bias the first electrode relative to the counter electrode, wherein the first electrode is in electrical communication with at least a portion of the metal layer during at least a portion of the electroless deposition process.

9. The method of claim 8, further comprising:
cleaning the surface of the substrate filling the one or more recesses, wherein cleaning comprises exposing a surface of a substrate to a liquid or a vapor selected from a group consisting of DI water, isopropyl alcohol, and an etchant solution.

10. The method of claim 8, wherein inhibiting the growth of the electrolessly deposited metal layer includes the process of removing material using one of the processes selected from the group consisting of chemical mechanical polishing, electrochemical mechanical polishing and electropolishing.

11. The method of claim 8, further comprising removing an adhesion-layer and/or a barrier layer from a field region of the substrate prior to filing one or more of the recesses.

12. The method of claim 11, wherein removing an adhesion-layer and/or a barrier layer is performed by use of a process selected from the group consisting of chemical mechanical polishing, electrochemical mechanical polishing and electropolishing.

13. The method of claim 8, further comprising depositing an electroless capping layer after filling the one or more recesses.

14. A cluster tool that is adapted to fill a substrate feature on a surface of a substrate, comprising:
at least one material removal chamber that is adapted to preferentially remove a metal layer from a field region rather than one or more recessed features formed on the surface of a substrate; and
at least one electroless plating cell that is adapted to deposit an electrolessly deposited layer on a surface of the substrate.

15. The cluster tool of claim 14, wherein the material removal chamber is adapted to remove the metal layer using electrochemical activity and is selected from a group consisting of an electrochemical mechanical polishing chamber or electropolishing chamber.

16. The cluster tool of claim 14, wherein the electrolessly deposited layer is formed in at least one of the one or more recessed features.

17. The cluster tool of claim 14, further comprising:
at least one cleaning modules is selected from a group consisting of a SRD chamber, a vapor dry chamber and brush module; and
an edge bead removal chamber.

18. A cluster tool that is adapted to fill a substrate feature on a surface of a substrate, comprising:
at least one electroless plating cell that is adapted to deposit an electrolessly deposited layer on a surface of the substrate and preferentially inhibit growth the electrolessly deposited layer on a field region on the surface of a substrate; and
at least one cleaning module.

19. The cluster tool of claim 18, wherein the at least one electroless plating cell comprises:
a substrate support that is adapted to receive a substrate on a substrate receiving surface;
a power source that is adapted to bias a portion of the substrate relative to an electrode; and
an electroless plating solution source that is adapted to position an electroless plating solution between the portion of the substrate and the electrode.

20. The cluster tool of claim 19, wherein the power supply is adapted to anodically bias the portion of the substrate relative to the electrode.

21. The cluster tool of claim 18, further comprising:
The at least one cleaning module is selected from a group consisting of a SRD chamber, a vapor dry chamber and brush module; and
an edge bead removal chamber.
